(19) United States
(12) Patent Application Publication
(10) Pub. No.: US 2026/0328717 A1
(43) Pub. Date: Oct. 22, 2026

(54) GAS SENSOR

(71) Applicant: NATIONAL TSING HUA UNIVERSITY, HSINCHU (TW)

(72) Inventors: Yu-Lun CHUEH, HSINCHU (TW); Tzu-Wen KUO, HSINCHU (TW)

(21) Appl. No.: 19/298,152

(22) Filed: Aug. 12, 2025

(30) Foreign Application Priority Data
Apr. 18, 2025 (TW) 114114847

(51) Int. Cl. G01N 27/12; C23C 16/30; C23C 16/50

(52) U.S. Cl. CPC G01N 27/125; C23C 16/30; C23C 16/50

(57) ABSTRACT

The present disclosure provides a gas sensor, which includes a sensing electrode module and a resistance meter, and the resistance meter is electrically connected to the sensing electrode module. The sensing electrode module includes a base layer, a plurality of sensing electrodes and a sensing layer. The sensing electrodes are disposed on one side of the base layer. The sensing layer covers the sensing electrodes, and the sensing layer includes a transition metal diselenide material.

### RELATED APPLICATIONS

This application claims priority to Taiwan Application Serial Number 114114847, filed Apr. 18, 2025, which is herein incorporated by reference.

### BACKGROUND

### Technical Field

The present disclosure relates to a sensor. More particularly, the present disclosure relates to a gas sensor.

### Description of Related Art

As technology rapidly advances, the demand for gas sensors with a high sensitivity and a high selectivity is growing day by day. The conventional gas sensors will decay after long-term use so as to affect the sensing reliability and the service lifetime of the gas sensors. Especially, the electrochemical gas sensors are easily influenced by harsh environments resulting in the bad sensing stability. The performance of the semiconductor gas sensor is less affected by the harsh environments, but the semiconductor gas sensor needs to be operated at a high temperature that increases the energy consumption cost and may produce adverse influence on the long-term use cost of the gas sensor.

Moreover, the sensing element of the gas sensor is easily corroded and damaged by corrosive gases during sensing the corrosive gases. Among these gases, hydrogen sulfide and ammonia gas, in particular, have a significantly detrimental effect on gas sensors, thus limiting the application of the gas sensor and increasing the maintenance cost of the gas sensor.

Therefore, developing a gas sensor that can sense at the room temperature, and have high environmental tolerance, high sensitivity and high selectivity has been the main goal of the industry.

### SUMMARY

According to one aspect of the present disclosure, a gas sensor includes a sensing electrode module and a resistance meter, and the resistance meter is electrically connected to the sensing electrode module. The sensing electrode module includes a base layer, a plurality of sensing electrodes and a sensing layer. The sensing electrodes are disposed on one side of the base layer. The sensing layer covers the sensing electrodes, wherein the sensing layer includes a transition metal diselenide material.

### BRIEF DESCRIPTION OF THE DRAWINGS

The present disclosure can be more fully understood by reading the following detailed description of the embodiment, with reference made to the accompanying drawings as follows:

FIG. 1 is a schematic view of a gas sensor according to one embodiment of the present disclosure.

FIG. 2 is a flow chart of a plasma assisted deposition method for preparing a transition metal diselenide material of the gas sensor according to the embodiment of the present disclosure.

FIG. 3 is a schematic view of a plasma-assisted chemical vapor reaction system used in the plasma assisted deposition method in FIG. 2.

FIG. 4A is a XRD diagram of Experimental example 1, Experimental example 2, Experimental example 3 and Experimental example 4.

FIG. 4B is a XRD diagram of Experimental example 7.

FIG. 4C is a XRD diagram of Experimental example 9.

FIG. 5 is a graph showing instantaneous sensing response results of Example 1, Example 2, Example 3 and Example 4 to nitrogen dioxide at concentrations ranging from 1 ppm to 25 ppm.

FIG. 6 is a sensing linearity graph of Example 1, Example 2, Example 3 and Example 4 with respect to different concentrations of nitrogen dioxide.

FIG. 7 is a sensing response graph of Example 1.

FIG. 8 is a sensing selectivity graph of Example 5, Example 6, Example 7 and Example 8.

FIG. 9 is a sensing response graph of Example 9 to sense different gases.

### DETAILED DESCRIPTION

The present disclosure will be further exemplified by the following specific embodiments. However, the embodiments can be applied to various inventive concepts and can be embodied in various specific ways. The specific embodiments are only for the purposes of description, and are not limited to these practical details thereof.

### <Gas Sensor>

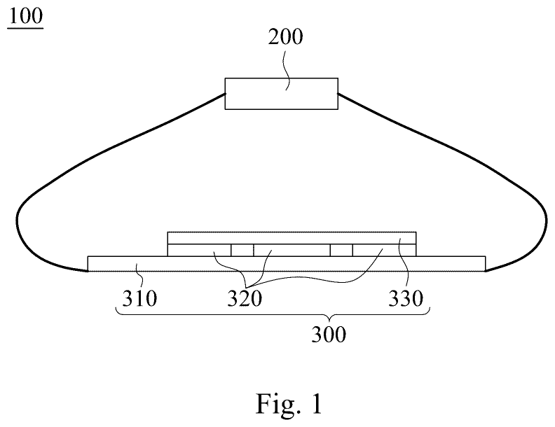

Reference is made to FIG. 1, and FIG. 1 is a schematic view of a gas sensor 100 according to one embodiment of the present disclosure. In FIG. 1, the gas sensor 100 includes a sensing electrode module 300 and a resistance meter 200, wherein the resistance meter 200 is electrically connected to the sensing electrode module 300. The sensing electrode module 300 includes a base layer 310, a plurality of sensing electrodes 320 and a sensing layer 330, wherein the sensing electrodes 320 are disposed on one side of the base layer 310, the sensing layer 330 covers the sensing electrodes 320, and the sensing layer 330 includes a transition metal diselenide material (its reference numeral is omitted). Specifically, the resistance value of the sensing electrode module 300 is measured by the resistance meter 200 during the gas sensor 100 sensing, so that the resistance value change of the sensing electrode module 300 is observed. Moreover, a distance between two of the sensing electrodes 320 can be 200 μm to 600 μm. Furthermore, the sensing electrodes 320 are composed of a chromium metal layer and a noble metal layer, wherein one surface of the chromium metal layer is configured to be connected to the base layer 310, the other surface of the chromium metal layer is connected to one surface of the noble metal layer, and the other surface of the noble metal layer is covered by the sensing layer 330. Further, a thickness of the chromium metal layer can be 1 nm to 10 nm, and a thickness of the noble metal layer can be 10 nm to 100 nm. Therefore, the sensing current of the gas sensor 100 can be enhanced, and the durability of the sensing electrodes 320 can be improved.

A thickness of the transition metal diselenide material can be 1.2 nm to 45 nm. Therefore, it is favorable for improving the charge transfer capacity of the transition metal diselenide material and the sensing sensitivity of the gas sensor 100. Moreover, the transition metal diselenide material can include a single crystal phase or a poly-crystal phase. Therefore, it is favorable for the selectivity of the gas sensor 100.

The transition metal diselenide material can include a transition metal layer and a selenium atom layer, the transition metal layer includes a transition metal source, and the selenium atom layer is covalently bonded to one side of the transition metal layer. Specifically, the transition metal source can be a molybdenum, a tungsten, a tin or a platinum. Therefore, it is favorable for the bonding stability of the selenium atom layer covalently bonded to the transition metal layer, and the durability and the reliability of the gas sensor 100.

Further, the transition metal source of the transition metal diselenide material can be molybdenum, tungsten, tin or platinum. Molybdenum, tungsten, tin and platinum are transition metals, the properties of the transition metals are among alkali metals, alkaline earth metals and nonmetals, and most of the transition metals have unfilled valence shell d-orbitals. Therefore, it is favorable for the bonding stability of the transition metal diselenide material. Moreover, the diselenide of molybdenum, tungsten, tin or platinum has a high environmental tolerance and a high selectivity to sense gases, and it is beneficial to improve the sensing performance of the gas sensor 100.

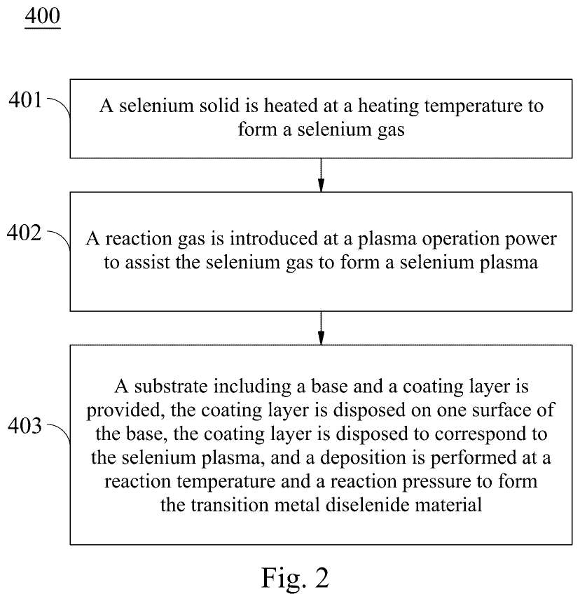

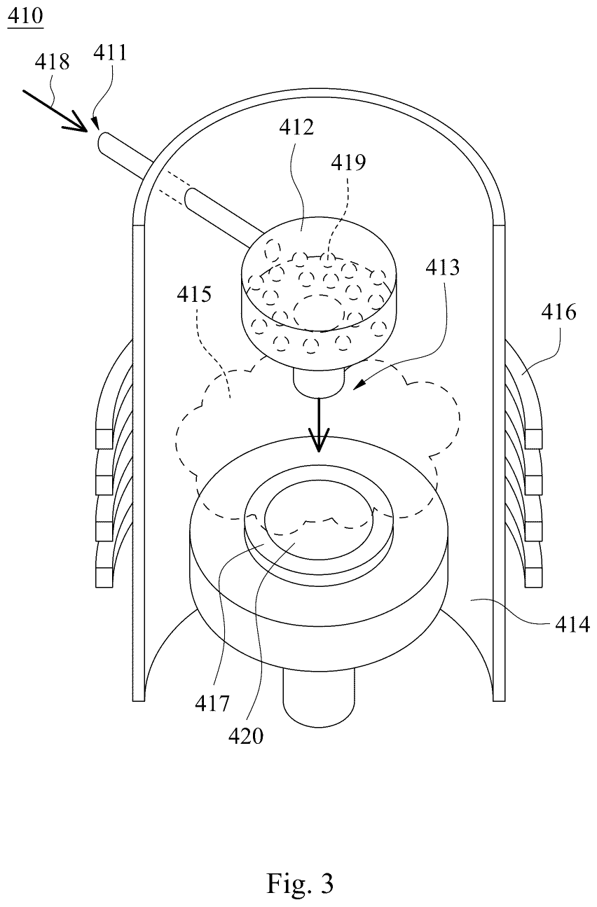

Reference is made to FIG. 2 and FIG. 3, FIG. 2 is a flow chart of a plasma assisted deposition method 400 for preparing a transition metal diselenide material 420 of the gas sensor 100 according to the embodiment of the present disclosure, and FIG. 3 is a schematic view of a plasma-assisted chemical vapor reaction system 410 used in the plasma assisted deposition method 400 in FIG. 2. In FIG. 2 and FIG. 3, the plasma assisted deposition method 400 includes step 401, step 402 and step 403.

In step 401, a selenium solid 419 is heated at a heating temperature to form a selenium gas (not shown), wherein the heating temperature is 150° C. to 300° C. Specifically, the selenium solid 419 is heated in a first space 412, and a temperature of the first space 412 is controlled within a range of 150° C. to 300° C. Therefore, the selenium solid 419 can stably convert into the selenium gas. Preferably, the heating temperature can be 200° C. to 300° C. Therefore, it is favorable for improving the conversion rate of the selenium solid 419 converting into the selenium gas.

In step 402, a reaction gas 418 is introduced at a plasma operation power to assist the selenium gas to form a selenium plasma 415, wherein the reaction gas 418 includes a nitrogen, a hydrogen or a combination thereof, and the plasma operating power is larger than 0 W and less than or equal to 500 W. In detail, the reaction gas 418 enters the first space 412 through a gas inlet 411 and is mixed with the selenium gas. The reaction gas 418 and the selenium gas flow out through a gas outlet 413, enter a second space 414, and correspond to an inductively coupled plasma (ICP) coil 416 in the second space 414 to form the selenium plasma 415. Moreover, a volume ratio of the nitrogen to the hydrogen in the reaction gas 418 can be 0:1, 1:3, 1:1, 3:1, 2:1 or 1:0. Therefore, it is favorable for the selenium plasma 415 forming. Furthermore, the volume ratio of the nitrogen to the hydrogen in the reaction gas 418 can be 1:1, 3:1, 2:1. Therefore, it is favorable for improving the generating efficiency of the selenium plasma 415. In detail, the hydrogen in the reaction gas 418 is affected by the inductively coupled plasma coil 416, and the selenium plasma 415 formed from the reaction gas 418 and the selenium gas can be represented as H₂Se, wherein H represents a hydrogen atom, and Se represents a selenium atom. Moreover, the selenium plasma 415 can be dissociated to form a precursor H₂Se⁺ with a high reactivity, and it is favorable for enhancing the reaction rate.

Moreover, a flow rate of the reaction gas 418 can be 1 sccm (standard cubic centimeter per minute) to 500 sccm. Therefore, it is favorable for enhancing a mixing uniformity of the reaction gas 418 and the selenium gas. Preferably, the flow rate of the reaction gas 418 can be 100 sccm to 500 sccm. Therefore, the generating efficiency of the selenium plasma 415 can be improved.

In step 403, a substrate 417 (not shown) including a base and a coating layer (not shown) is provided, the coating layer is disposed on one surface of the base, the coating layer is disposed to correspond to the selenium plasma 415, and a deposition is performed at a reaction temperature and a reaction pressure to form the transition metal diselenide material 420. A thickness of the coating layer is 1 nm to 40 nm, and the coating layer includes a transition metal source. Therefore, the transition metal diselenide material 420 is formed after the reaction of the selenium plasma 415 and the coating layer. In detail, the precursor H₂Se⁺ formed from the dissociation of the selenium plasma 415 reacts with the coating layer to form chemical bonds so as to form the transition metal diselenide material 420. When the thickness of the coating layer is 1 nm to 40 nm, it is favorable for the generation efficiency of the transition metal diselenide material 420. Preferably, the thickness of the coating layer can be 1 nm to 20 nm. Therefore, the transition metal diselenide material 420 can be thinned, and the charge transfer capacity of the transition metal diselenide material 420 can be enhanced. Moreover, the transition metal source of the coating layer can be molybdenum, tungsten, tin or platinum. Therefore, it is favorable for the bonding stability of the transition metal and the selenium, and it is beneficial to enhance the sensing stability of the gas sensor 100.

Moreover, the reaction temperature can be 100° C. to 550° C., and the reaction pressure can be 0.01 torr to 760 torr. Therefore, the yield of the transition metal diselenide material 420 can be improved. Preferably, the reaction temperature can be 250° C. to 550° C., the lattice structure of the transition metal diselenide material 420 can be improved, it is beneficial to enhance the chemical resistance of the transition metal diselenide material 420, and it is favorable for depositing the transition metal diselenide material 420 on a base with a low melting point. Therefore, the corrosion resistance of the gas sensor 100 can be improved.

In detail, a material of the base can be polyimide, glass, silicon nitride, stainless steel, silicon dioxide, aluminum oxide or hafnium oxide. Therefore, the application diversity of the transition metal diselenide material 420 can be increased. For example, when the material of the base is polyimide, it is beneficial to apply the transition metal diselenide material 420 on a flexible printed circuit board.

The following specific embodiments further illustrate the present disclosure for those with ordinary skill in the technical field to utilize and realize the present disclosure without excessive interpretation. These embodiments should not limit the scope of the present disclosure, but illustrate how to implement the materials and methods of the present disclosure.

### <Transition Metal Diselenide Material>

Experimental example 1: the transition metal diselenide material of Experimental example 1 (hereinafter referred to as Experimental example 1) was prepared via the aforementioned plasma assisted deposition method, wherein the heating temperature was 150° C. to 300° C., the plasma operation power was larger than 0 W and less than or equal to 500 W, the reaction temperature was 100° C. to 550° C., the reaction pressure was 0.01 torr to 760 torr, the volume ratio of the nitrogen to the hydrogen in the reaction gas was 3:1, the material of the base was silicon dioxide, the coating layer was a tin oxide layer, and a thickness of the tin oxide layer was 1 nm to 40 nm.

The transition metal diselenide material of Experimental example 2 (hereinafter referred to as Experimental example 2), the transition metal diselenide material of Experimental example 3 (hereinafter referred to as Experimental example 3), and the transition metal diselenide material of Experimental example 4 (hereinafter referred to as Experimental example 4) were prepared via the aforementioned plasma assisted deposition method that was similar to Experimental example 1. The difference is the volume ratio of the nitrogen to the hydrogen in the reaction gas.

The transition metal diselenide material of Experimental example 5 (hereinafter referred to as Experimental example 5), the transition metal diselenide material of Experimental example 6 (hereinafter referred to as Experimental example 6), the transition metal diselenide material of Experimental example 7 (hereinafter referred to as Experimental example 7), the transition metal diselenide material of Experimental example 8 (hereinafter referred to as Experimental example 8), and the transition metal diselenide material of Experimental example 9 (hereinafter referred to as Experimental example 9) were prepared via the aforementioned plasma assisted deposition method that was similar to Experimental example 1. The difference is the coating layer and the volume ratio of the nitrogen to the hydrogen in the reaction gas. The coating layers of Experimental example 5 to Experimental example 8 were all molybdenum oxide layers, and the thicknesses of the coating layers were 1 nm to 40 nm. The coating layer of Experimental example 9 was a platinum metal layer, and the thickness of the coating layer was 1.2 nm.

The coating layers and the volume ratios of the nitrogen to the hydrogen in the reaction gas of Experimental example 1 to Experimental example 9 were shown in Table 1.

TABLE 1

| transition metal | | volume ratio of nitrogen to |
|---|---|---|
| diselenide | | hydrogen in reaction gas |
| material | coating layer | (nitrogen:hydrogen) |
| Experimental | tin oxide layer | 3:1 |
| example 1 | | |
| Experimental | tin oxide layer | 1:1 |
| example 2 | | |
| Experimental | tin oxide layer | 1:3 |
| example 3 | | |
| Experimental | tin oxide layer | 0:1 |
| example 4 | | |
| Experimental | molybdenum | 3:1 |
| example 5 | oxide layer | |
| Experimental | molybdenum | 2:1 |
| example 6 | oxide layer | |
| Experimental | molybdenum | 1:1 |
| example 7 | oxide layer | |
| Experimental | molybdenum | 1:3 |
| example 8 | oxide layer | |
| Experimental | platinum metal | 1:1 |
| example 9 | layer | |

### <Lattice Structure of Transition Metal Diselenide Material>

The lattice structures of transition metal diselenide materials of Experimental example 1 to Experimental example 4 were analyzed using an X-rat diffractometer (XRD). The scanning rate of XRD was 2° per minute, the scanning rage was within 10° to 50°, and the scanning step was 0.05°.

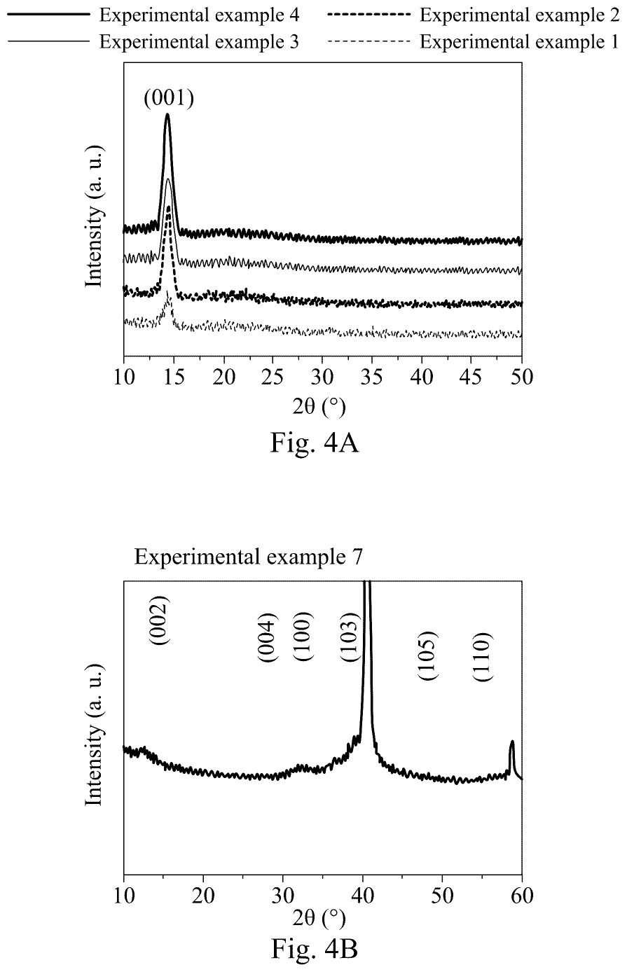

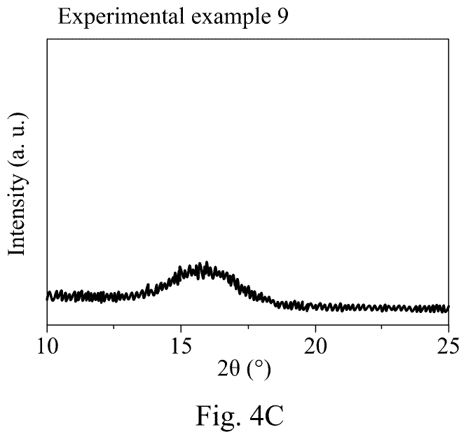

Reference is made to FIG. 4A to FIG. 4C, FIG. 4A is a XRD diagram of Experimental example 1, Experimental example 2, Experimental example 3 and Experimental example 4, FIG. 4B is a XRD diagram of Experimental example 7, and FIG. 4C is a XRD diagram of Experimental example 9. In FIG. 4A to FIG. 4C, 20 signals of tin diselenide of the transition metal diselenide materials of Experimental example 1, Experimental example 2, Experimental example 3 and Experimental example 4 are respectively at 13.5°, 20 signals of molybdenum diselenide of the transition metal diselenide material of Experimental example 7 are respectively at 13.5°, 27.5°, 31.5°, 38°, 47.5° and 56°, and a 20 signal of platinum diselenide of the transition metal diselenide material of Experimental example 9 is at 17.5°. It can prove that the transition metal diselenide material can be prepared via the plasma assisted deposition method.

### <Sensing Result of Gas Sensor>

A gas sensor includes a sensing electrode module and a resistance meter, wherein the resistance meter is electrically connected to the sensing electrode module. The sensing electrode module includes a base layer, a plurality of sensing electrodes, and a sensing layer, wherein the sensing electrodes are disposed on one side of the base layer, the sensing layer covers the sensing electrodes, and the sensing layer includes the transition metal diselenide material of the aforementioned Experimental examples. Moreover, thicknesses of the transition metal diselenide materials can be 1.2 nm to 45 nm. Gas sensors of Example 1 to Example 9 (hereinafter referred to as Example 1 to Example 9) and the transition metal diselenide materials of Example 1 to Example 9 are shown in Table 2.

TABLE 2

| Gas sensor | transition metal diselenide material |
|---|---|
| Example 1 | Experimental example 1 |
| Example 2 | Experimental example 2 |
| Example 3 | Experimental example 3 |
| Example 4 | Experimental example 4 |
| Example 5 | Experimental example 5 |
| Example 6 | Experimental example 6 |
| Example 7 | Experimental example 7 |
| Example 8 | Experimental example 8 |
| Example 9 | Experimental example 9 |

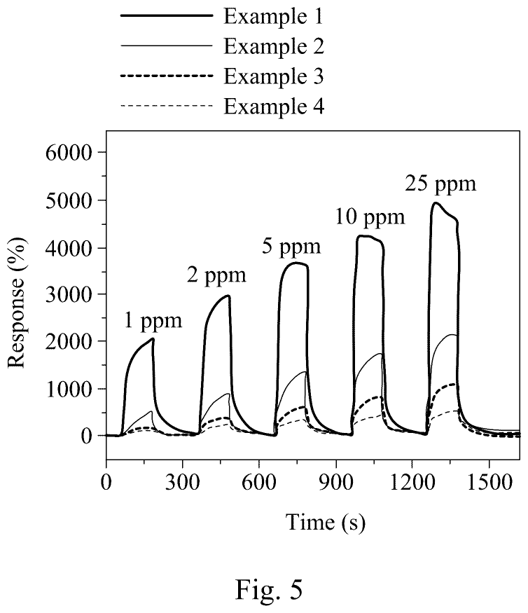

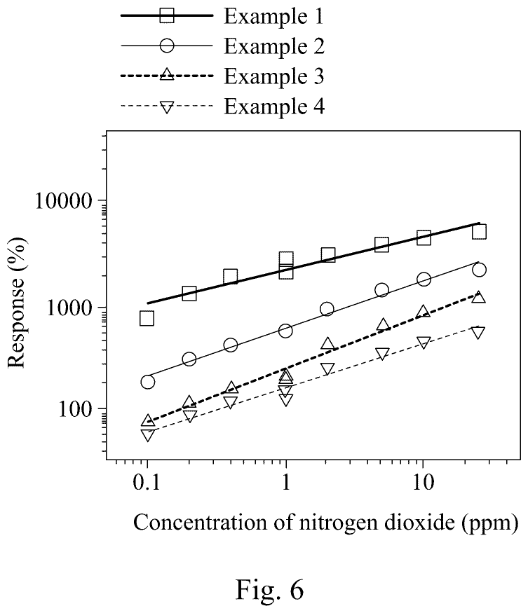

Reference is made to FIG. 5 and FIG. 6, FIG. 5 is a graph showing instantaneous sensing response results of Example 1, Example 2, Example 3 and Example 4 to nitrogen dioxide at concentrations ranging from 1 ppm to 25 ppm, and FIG. 6 is a sensing linearity graph of Example 1, Example 2, Example 3 and Example 4 with respect to different concentrations of nitrogen dioxide. The sensing response can be measured by the following equation:

$$Response ( \% ) = \frac{( {R}_{q a s} - {R}_{a i r} )}{{R}_{a i r}} \times 100 \% ,$$

wherein Rₐᵢᵣ is the resistance value in pure air, and R_{gas} is the resistance value during sensing gases.

In FIG. 5 and FIG. 6, as the concentration of nitrogen dioxide increases, the responses of the gas sensors of Example 1, Example 2, Example 3 and Example 4 increase, respectively. Further, the R-square of the linear regression is measured from the response data so as to evaluate the sensing linearity. The R-square results of Example 1, Example 2, Example 3 and Example 4 are respectively 0.922, 0.983, 0.980 and 0.972. It can prove that the gas sensor of the present disclosure can sense nitrogen dioxide, and has a good sensing linearity. In detail, the response of Example 1 is the largest, and it shows that the nitrogen in the reaction gas in the plasma assisted deposition method is favorable for increasing the sensing signal strength and the sensitivity of the gas sensor with the transition metal diselenide material.

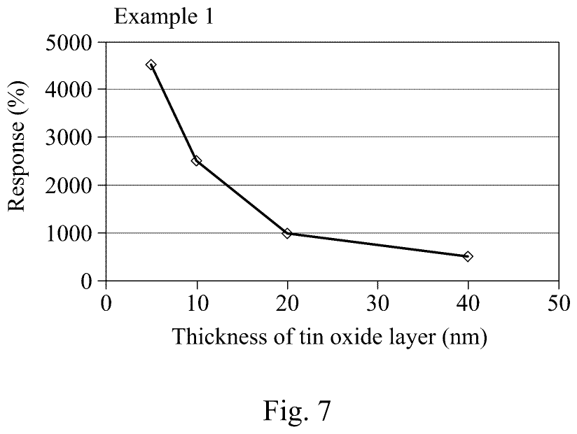

Reference is made to FIG. 7, which is a sensing response graph of Example 1. In detail, the coating layer of Experimental example 1 is the tin oxide layer, the thickness range of the tin oxide layer is 1 nm to 40 nm, and Experimental example 1 with the tin oxide layers of different thicknesses applied to gas sensors so as to obtain the gas sensors of Example 1. In FIG. 7, Example 1 with the tin oxide layers of different thicknesses has response. Moreover, when the thickness of the tin oxide layer is less than or equal to 20 nm, the response intensity is greater, and it is beneficial to enhance the sensing sensitivity of the gas sensor.

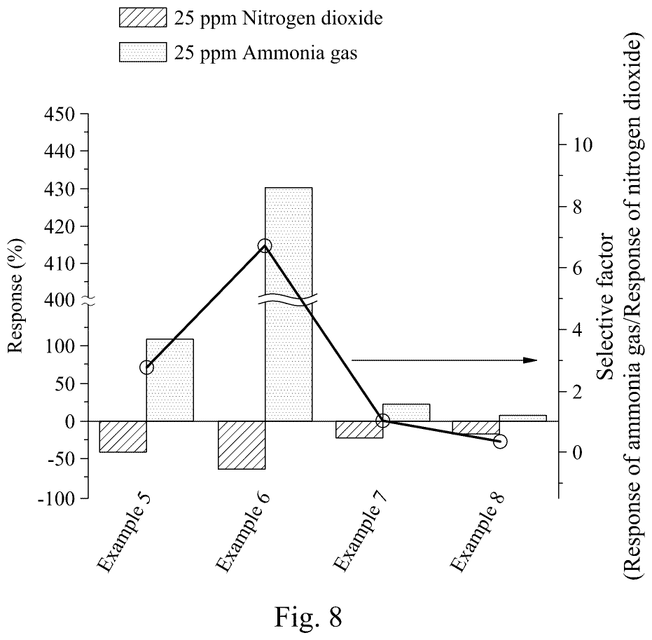

Reference is made to FIG. 8, which is a sensing selectivity graph of Example 5, Example 6, Example 7 and Example 8. In FIG. 8, when Example 5, Example 6, Example 7 and Example 8 were respectively used to sense 25 ppm of nitrogen dioxide and 25 ppm of ammonia gas, and the responses were obtained. It can prove that Example 5, Example 6, Example 7 and Example 8 can be used to sense nitrogen dioxide and ammonia gas, wherein a ratio of the response of ammonia gas to the response of nitrogen dioxide is a selective factor. When the selective factor is higher, the selectivity for sensing ammonia gas is higher. Example 5, Example 6, Example 7 and Example 8 of the present disclosure respectively have a high selectivity for sensing ammonia gas.

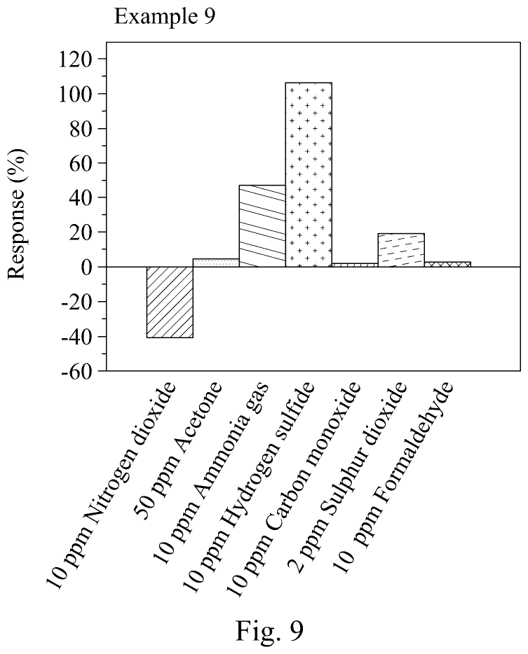

Reference is made to FIG. 9, which is a sensing response graph of Example 9 to sense different gases. In FIG. 9, Example 9 shows sensing response to nitrogen dioxide, acetone, ammonia gas, hydrogen sulfide, carbon monoxide, sulphur dioxide and formaldehyde. It can prove that Example 9 of the present disclosure can be used to sense nitrogen dioxide, acetone, ammonia gas, hydrogen sulfide, carbon monoxide, sulphur dioxide and formaldehyde. Example 9 has a high response to sense ammonia gas and hydrogen sulfide, and thus has a high selectivity for sensing ammonia gas and hydrogen sulfide.

In conclusion, the sensing layer of the gas sensor of the present disclosure includes the transition metal diselenide material, and the transition metal diselenide material can be prepared via the plasma assisted deposition method through the plasma-assisted chemical vapor reaction system to form the transition metal diselenide material with a large area. The structure and the composition of the transition metal diselenide material are adjusted to achieve the high selectivity to specific gas molecules, and the transition metal diselenide material can be applied in sensing corrosive gases, such as hydrogen sulfide, ammonia gas or sulphur dioxide. Therefore, the performance of the gas sensor of the present disclosure is less affected by corrosive gases in harsh environments, and the gas sensor has advantages of high sensitivity, high selectivity, reproducibility and low power consumption. Moreover, the transition metal diselenide material prepared via the plasma assisted deposition method can achieve high efficiency and accuracy in the production, and the transition metal diselenide material can be fabricated with a large wafer-scale and a large area, whereby a high quality of the transition metal diselenide material can be ensured.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A gas sensor, comprising:
a sensing electrode module, comprising:
a base layer;
a plurality of sensing electrodes disposed on one side of the base layer; and
a sensing layer covering the sensing electrodes, wherein the sensing layer comprises a transition metal diselenide material; and
a resistance meter electrically connected to the sensing electrode module.

2. The gas sensor of claim 1, wherein a thickness of the transition metal diselenide material is 1.2 nm to 45 nm.

3. The gas sensor of claim 1, wherein the transition metal diselenide material comprises a single crystal phase or a polycrystal phase.

4. The gas sensor of claim 1, wherein the transition metal diselenide material comprises:
a transition metal layer comprising a transition metal source; and
a selenium atom layer covalently bonded to one side of the transition metal layer.

5. The gas sensor of claim 4, wherein the transition metal source of the transition metal diselenide material is a molybdenum, a tungsten, a tin or a platinum.

6. The gas sensor of claim 1, wherein the transition metal diselenide material is prepared by a plasma assisted deposition method.

7. The gas sensor of claim 6, wherein the plasma assisted deposition method comprises:
heating a selenium solid at a heating temperature to form a selenium gas, wherein the heating temperature is 150° C. to 300° C.;
introducing a reaction gas at a plasma operation power to assist the selenium gas to form a selenium plasma, wherein the reaction gas comprises a nitrogen, a hydrogen or a combination thereof, the plasma operation power is larger than 0 W and less than or equal to 500 W; and
providing a substrate, wherein the substrate comprises a base and a coating layer, the coating layer is disposed on one surface of the base, the coating layer is disposed to correspond to the selenium plasma, a deposition is performed at a reaction temperature and a reaction pressure to form the transition metal diselenide material, a thickness of the coating layer is 1 nm to 40 nm, and the coating layer comprises a transition metal source.

8. The gas sensor of claim 7, wherein a volume ratio of the nitrogen to the hydrogen in the reaction gas is 0:1, 1:3, 1:1, 3:1, 2:1 or 1:0.

9. The gas sensor of claim 8, wherein the volume ratio of the nitrogen to the hydrogen in the reaction gas is 1:1, 3:1, 2:1.

10. The gas sensor of claim 7, wherein the reaction temperature is 100° C. to 550° C.
